(19) United States
(12) Patent Application Publication
(10) Pub. No.: US 2026/0293732 A1
(43) Pub. Date: Sep. 24, 2026

(54) CIRCUIT BOARD AND METHOD FOR MANUFACTURING THE SAME AND SEMICONDUCTOR PACKAGE

(71) Applicant: LG INNOTEK CO., LTD., Seoul (KR)

(72) Inventors: Na Mu MIN, Seoul (KR); Byung Wook WOO, Seoul (KR); Jae Hyoun YOO, Seoul (KR); Hyun PARK, Seoul (KR); Hyung Sub LEE, Seoul (KR)

(21) Appl. No.: 19/573,177

(22) Filed: Mar. 20, 2026

(30) Foreign Application Priority Data
Mar. 21, 2025 (KR) 10-2025-0036680

(51) Int. Cl. H10W 70/685; H05K 1/03; H05K 1/11; H10W 70/63

(52) U.S. Cl. CPC H10W 70/685; H05K 1/0366; H05K 1/115; H10W 70/63; H05K 2201/029

(57) ABSTRACT

The present embodiment relates to a circuit board and semiconductor package. The circuit board according to one aspect of the present invention comprises: an insulating layer including resin and glass fibers disposed within the resin; and a circuit portion disposed on the insulating layer, wherein the glass fibers include first glass fibers extending in a first horizontal direction and second glass fibers disposed on the first glass fibers and extending in a second horizontal direction, wherein the cross-section of the first glass fibers and the cross-section of the second glass fibers are disposed on the cross-section of said circuit portion, wherein the first glass fiber includes a plurality of regions disposed such that its thickness in the vertical direction varies along a third horizontal direction forming a predetermined angle with the first horizontal direction, and the second glass fiber includes a plurality of cross-section portions disposed spaced apart along the third horizontal direction.

### CROSS-REFERENCE TO RELATED APPLICATION

This application claims priority under 35 U.S.C. § 119 to Korean Application No. 10-2025-0036680 filed on Mar. 21, 2025, whose entire disclosure is hereby incorporated by reference.

### Technical Fields

The teachings in accordance with exemplary and non-limiting embodiments of the present invention relate generally to a circuit board and method for manufacturing the same and semiconductor package.

### Background of Arts

Recent trends in electronic technologies such as AI and servers are moving towards multifunctionality and high-speed operation, and to respond to these trends, circuit board technologies for high-layer count and large-area production are also advancing rapidly, keeping pace with the fast-developing semiconductor chip manufacturing technology.

Particularly, as the density of transistors and wiring within semiconductor chips increases, the number of I/O terminals on these chips is rising. To address this trend, circuit boards are not only becoming finer in terms of wiring density, length, and width, but also progressing towards high-layer count and large-area designs.

Furthermore, from the perspective of miniaturizing finished electronic products, the thickness of applied circuit boards is also decreasing, and technologies related to multilayer circuit boards, which incorporate more circuit layers within boards of the same thickness, are being actively researched. Additionally, as semiconductor chip pitches become narrower and chip sizes increase, research is underway into chiplet technology, which separates semiconductor chips by function. Furthermore, technologies for connecting these separated chiplets on the circuit board are being actively researched. Moreover, by connecting semiconductor chips with different functions on the circuit board, technologies concerning the interconnection relationship between the circuit board and semiconductor chips—such as the circuit board connecting semiconductor chips together—are being actively researched. This represents a shift from the traditional perspective of considering the circuit board solely from the standpoint of semiconductor packaging.

A circuit board refers to an insulating substrate with conductive material such as copper arranged in circuit line patterns, collectively denoting the package board immediately prior to mounting electronic components. To densely mount numerous electronic components of various types onto a flat plate, the mounting positions for each component are determined, and the circuit patterns connecting the components are printed onto the plate surface and fixed.

Recently, as the number of signals semiconductor chips must process increases, there is a trend towards larger chip sizes. Consequently, the size of the circuit boards onto which these semiconductor chips are mounted is also increasing.

With the trend towards higher-layer counts and larger areas for circuit boards, the warpage characteristics of the board become a critical factor for its reliability.

For example, a circuit board comprises a core layer and multiple build-up structures symmetrically arranged vertically relative to the core layer. Each of the multiple build-up structures includes multiple insulating layers arranged vertically. The multiple build-up structures are electrically interconnected by core via electrodes penetrating the core layer.

To enhance the durability against bending of the circuit board, the insulating layers constituting the circuit board comprise resin and reinforcing material disposed within the resin. For instance, the reinforcing material may be glass fiber. However, when insulating layers containing glass fiber are deployed, the high dielectric constant of the glass fiber itself causes a problem where the signal transmission efficiency within the circuit board's circuitry deteriorates.

### Prior Technical Document

### Patent Document

Korean Patent Gazette No.: 10-2024-0158112(laid out on Nov. 04, 2024. 11)

### Summary of Invention

### Technical Subjects

The present invention is to provide a circuit board and semiconductor package that minimizes signal loss in circuit portions caused by glass fibers by adjusting the glass fibers that form an insulating layer and the arrangement structure of the circuit portions.

### Technical Solutions

The circuit board according to this embodiment may comprise: an insulating layer including resin and glass fibers disposed within the resin; and a circuit portion disposed on the insulating layer, wherein the glass fibers include first glass fibers extending in a first horizontal direction and second glass fibers disposed on the first glass fibers and extending in a second horizontal direction, wherein the cross-section of the first glass fibers and the cross-section of the second glass fibers are disposed on the cross-section of the circuit portion, wherein the first glass fiber includes a plurality of regions disposed such that its thickness in the vertical direction varies along a third horizontal direction forming a predetermined angle with the first horizontal direction, and the second glass fiber includes a plurality of cross-section portions disposed spaced apart along the third horizontal direction.

The semiconductor package according to another aspect of the present invention may comprise: an insulating layer including resin and glass fibers disposed within the resin; a semiconductor chip disposed on the insulating layer; and a circuit portion disposed on the insulating layer, wherein the glass fibers include first glass fibers extending in a first horizontal direction and second glass fibers disposed on the first glass fibers and extending in a second horizontal direction, wherein the cross-section of the first glass fibers and the cross-section of the second glass fibers are disposed on the cross-section of the circuit portion, wherein the first glass fiber includes a plurality of regions disposed such that its thickness in the vertical direction varies along a third horizontal direction forming a predetermined angle with the first horizontal direction, and the second glass fiber includes a plurality of cross-section portions disposed spaced apart along the third horizontal direction.

### Advantageous Effects

According to the present embodiments, by arranging the circuit portion to be tilted relative to the glass fibers within the insulating layer, the vertically overlapping area between the glass fibers and the circuit portion can be minimized.

Consequently, in the signal transmission of multiple circuit portions arranged within the circuit board, there is the advantage of being able to reduce signal loss compared to conventional methods and improve power transmission efficiency.

### BRIEF DESCRIPTION OF DRAWINGS

FIG. 1 is a cross-sectional view of a circuit board according to an embodiment of the present invention.

FIG. 2 is a diagram illustrating the arrangement structure of the via electrode within the first core layer, second core layer, and upper build-up insulating portion according to an embodiment of the present invention.

FIG. 3 is a diagram showing a cross-section of the core portion according to an embodiment of the present invention.

FIG. 4 is an enlarged photograph of the via hole, which is the arrangement area of the second via electrode within the second core layer according to an embodiment of the present invention.

FIG. 5 is an illustration showing the arrangement structure of glass fibers within the insulating layer according to an embodiment of the present invention.

FIGS. 6 and 7 (a) and (b) are illustrations for explaining signal loss according to the arrangement structure of glass fibers and circuit portions.

FIGS. 8 (a) and (b) are diagrams illustrating the arrangement structure of glass fibers and circuitry according to a comparative example.

FIGS. 9 (a) to 11 (b) are various diagrams illustrating the arrangement structure of glass fibers and circuitry according to embodiments of the present invention.

FIG. 12 is a table comparing signal loss between a circuit board according to a comparative example and a circuit board according to an embodiment of the present invention.

FIG. 13 is a diagram illustrating a semiconductor package according to an embodiment of the present invention.

### BEST MODES

Hereinafter, the attached drawings are referred to in detail to explain the preferred embodiment of the present invention.

However, the technical idea of the present invention is not limited to the some embodiments described, but can be implemented in various different forms, and within the scope of the technical idea of the present invention, one or more of the components between the embodiments can be selectively combined or replaced.

In addition, the terms used in the embodiments of the present invention (including technical and scientific terms) can be interpreted to mean what a person with ordinary skill in the art would understand, unless explicitly defined and described, and generally understood by a person with ordinary skill in the art. Generally used terms, such as those defined in dictionaries, can be interpreted in the context of the relevant technology.

Furthermore, the terms used in the embodiments of the present invention are intended to explain the embodiments and are not intended to limit the invention. In this specification, the singular form may include the plural form unless otherwise specified in the text, and when described as ‘A and (and/and) B, C, at least one (or more than one) of A, B, and C,’ it may include one or more of all combinations of A, B, and C.

In addition, terms such as 1, 2, A, B, (a), and (b) may be used to describe the components of the embodiments of the present invention. Such terms are intended only to distinguish the component from other components and are not limited by the nature, order, or sequence of the component.

And, if any component is described as being ‘connected’, ‘coupled’ or ‘attached’ to another component, that component may be directly connected, coupled or attached to that other component, as well as being ‘connected’, ‘coupled’ or ‘attached’ to another component that is between that component and that other component.

In addition, when it is stated that each component is formed or arranged ‘above or below’, the above or below includes not only the case where two components are directly in contact with each other, but also the case where one or more other components are formed or arranged between the two components. In addition, when it is expressed as ‘upper or lower’, it can include the meaning of the lower direction as well as the upper direction based on one component.

Furthermore, the expression that configuration A is disposed between configurations B and C must also encompass the meaning that configuration A is disposed such that at least part of it overlaps horizontally and/or vertically with configurations B and C.

Expressions denoting direction include horizontal direction and vertical direction, and the horizontal direction encompasses directions such as a first horizontal direction, a second horizontal direction, and a third horizontal direction. The vertical direction encompasses directions such as a first vertical direction, a second vertical direction, and a third horizontal direction. At least one of the first vertical direction, second vertical direction, and third vertical direction denotes a direction perpendicular to at least one horizontal direction, or denotes a direction perpendicular to all horizontal directions. However, unless otherwise specified, the vertical direction shall be defined as a direction perpendicular to all horizontal directions. Furthermore, some of the aforementioned first horizontal direction, second horizontal direction, and third horizontal direction may be mutually perpendicular; for convenience in subsequent descriptions, mutually perpendicular directions shall be defined accordingly.

Furthermore, the meaning that configuration A is exposed from configuration B should be understood as meaning that configuration A is exposed from configuration B, not that it is exposed from the entire product. That is, when it is stated that configuration A is exposed from configuration B, it should be understood to mean that configuration A is at least partially covered by configuration C.

Furthermore, when it is stated that configuration A “contacts” configuration B, this may include not only cases where the component directly “contacts” the other component, but also cases where “contact” occurs via another configuration situated between the two configurations. Therefore, if it is intended that configuration A only “directly contacts” configuration B, it shall be stated as “directly contacting”.

Furthermore, where it is stated that configuration A is “covered” by configuration B, this should be understood to mean that configuration A is covered by configuration B, such that a portion of it is obscured for the functionality and purpose being addressed. Unless there are special circumstances, it must not be understood to mean that configuration A is entirely covered by configuration B.

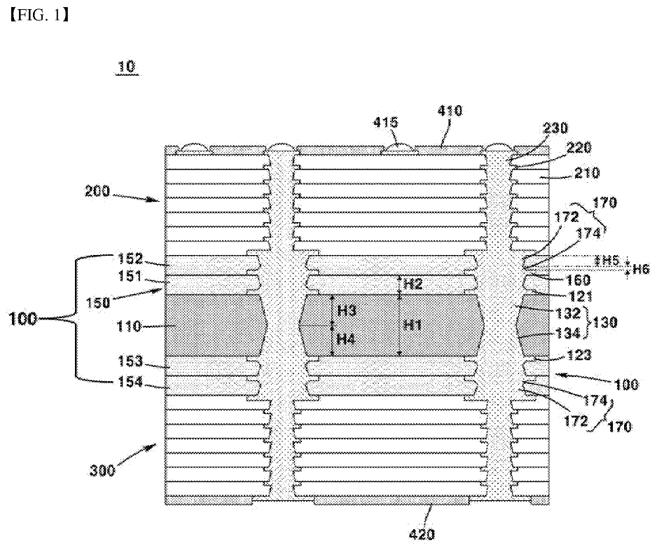

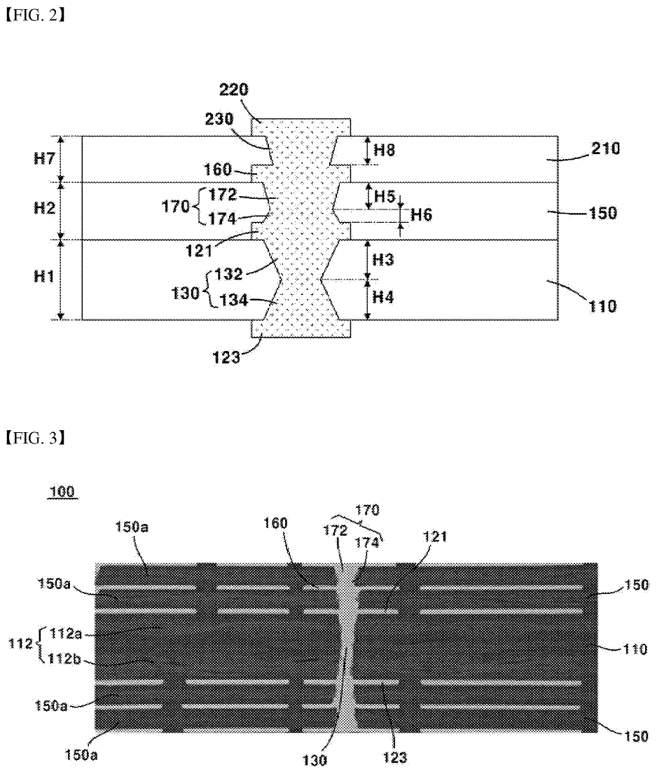

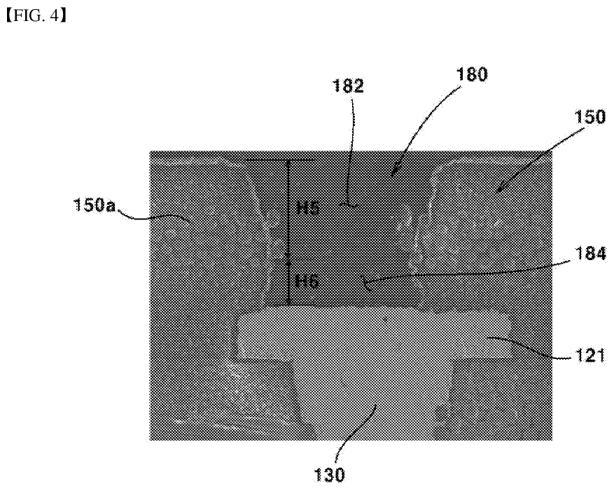

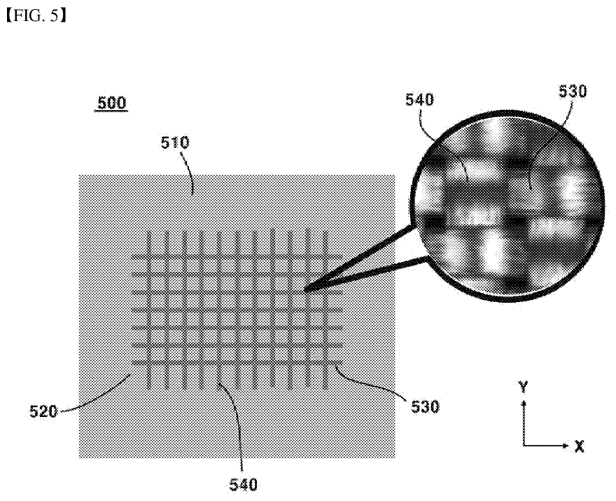

FIG. 1 is a cross-sectional view of a circuit board according to an embodiment of the present invention, FIG. 2 is a diagram illustrating the arrangement structure of the via electrode within the first core layer, second core layer, and upper build-up insulating portion according to an embodiment of the present invention, FIG. 3 is a diagram showing a cross-section of the core portion according to an embodiment of the present invention, and FIG. 4 is an enlarged photograph of the via hole, which is the arrangement area of the second via electrode within the second core layer according to an embodiment of the present invention.

Referring to FIGS. 1 to 4, the circuit board (10) according to an embodiment of the present invention may comprise a core portion (100), an upper build-up structure (200), a lower build-up structure (300), and protective layers (410, 420).

The circuit board (10) may include a core portion (100). The core portion (100) may be a member forming the foundation of the circuit board (10). Based on the vertical direction, the core portion (100) may be disposed at the center of the circuit board (10). The material of the core portion (100) may comprise at least one selected from the group consisting of glass, resin, plastic, and metal. For example, the core portion (100) may comprise resin and glass fibers embedded within the resin. As the rigidity of the core portion (100) increases through the glass fibers, the bending characteristics of the circuit board (10) can be improved.

Recently, as the number of signals that semiconductor chips must process increases, there is a trend towards larger-area semiconductor chips. Accordingly, the size of the circuit boards onto which these semiconductor chips are mounted is also increasing.

According to the embodiment, to improve the bending characteristics of the circuit board (10) in response to its increased number of layers and large area, it is preferable to form the thickness of the core portion (100) thicker.

The core assembly (100) may comprise a first core layer (110) and a second core layer (150) disposed on one surface and the opposite surface of the first core layer (110). The second core layer (150) may be disposed on the upper surface and the lower surface of the first core layer (110), respectively.

By way of example, the second core layer (150) may comprise multiple insulating layers stacked vertically. Relative to the first core layer (110), the second core layer (150) may comprise a second-1 core layer (151) disposed upon the first core layer (110), a second-2 core layer (152) disposed on the second-1 core layer (151), a second-3 core layer (153) disposed on the bottom surface of the first core layer (110), and a second-4 core layer (154) disposed on the lower surface of the second-3 core layer (153). However, this is not limiting, and relative to the first core layer (110), the second core layer (150) may also be implemented as a single layer on both the upper and lower surfaces of the first core layer (110). Furthermore, to control the overall thickness of the core portion (100), the second core layer (150) may have a structure where a greater number of insulating layers are stacked vertically. Moreover, by arranging the number of stacked second core layers (150) on the upper and lower parts of the first core layer (110) differently, warping occurring during the circuit board manufacturing process or warping occurring after the process can be precisely controlled.

With respect to the vertical direction, the thickness (H1) of the first core layer (110) may be greater than the thickness (H2) of the second core layer (150). Here, the thickness (H2) of the second core layer (150) may denote the vertical thickness of each of the multiple insulating layers constituting the second core layer (150). According to the exemplary embodiment, the thickness (H1) of the first core layer (110) may be 100 μm or more and 300 μm or less to improve the warpage characteristics of the circuit board (10) and the processability of the first via electrode (130) described later. For example, the first via electrode (130) penetrating the first core layer (110) is advantageously configured such that the entire via hole penetrating the first core layer (110) is filled with metal. This facilitates improved mechanical properties, such as heat dissipation, and/or electrical properties, such as power and signal transmission.

However, if the thickness of the first core layer (110) exceeds 300 μm, it becomes difficult to completely fill the via hole with metal, and the processing of the via hole also becomes difficult. Therefore, it is desirable for the thickness of the first core layer (110) to be within the aforementioned range. Furthermore, the thicknesses (H2) of the second-1 core layer (151), the second-2 core layer (152), the second-3 core layer (153), and the second-4 core layer (154) may each have a thickness (H2) of 60 μm or more and 80 μm or less to improve the bending characteristics of the circuit board (10) and to favorably control the overall thickness of the core portion (100). In this case, the ratio of the thicknesses of the first core layer (110) and the second core layer (110) may be 5:1 to 5:4.

If the ratio of the thickness of the second core layer (150) to that of the first core layer (110) is less than 5:1, the thickness of the core portion (100) may not be sufficiently secured. Consequently, warpage issues may arise in the circuit board (10) due to reduced durability.

Where the ratio of the thickness of the second core layer (150) to that of the first core layer (110) exceeds 5:4, the manufacturing cost for forming the core portion (100) increases relatively, or yield and productivity decrease. Consequently, the utility of implementing the core portion (100) through multiple insulating layers diminishes. and the process for forming the second via electrode (170) within the second core layer (150), described later, also becomes problematic.

The first core layer (110) may comprise resin and glass fibers (112) disposed within the resin. The first core layer (110) may be a prepreg (PPG). For example, the first core layer (110) may comprise multiple glass fibers (112). Each of the multiple glass fibers (112) extends in a horizontal direction and may be disposed perpendicular to one another. As illustrated in FIG. 3, the multiple glass fibers (112) may include a first glass fiber (112a) and a second glass fiber (112b) disposed beneath the first glass fiber (112a).

The second core layer (150) may comprise a resin and glass fibers (150a) disposed within the resin. The second core layer (150) may be a prepreg (PPG). Within the resin constituting the second core layer (150), glass fibers (150a) may be disposed in a horizontal direction. As shown in FIG. 3, a single layer of glass fibers (150a) may be disposed within the second core layer (150).

According to the embodiment, by implementing the glass fibers (112) within the first core layer (110) in a plurality of layers exceeding those of the glass fibers (150a) within the second core layer (150), the bending characteristics of the circuit board (10) can be improved via the first core layer (110) disposed centrally in the vertical direction.

Furthermore, by implementing the core portion (100) with a structure where the second core layer (150), which is thinner than the first core layer (110), is stacked vertically, it is easier to control the overall thickness of the core portion (100) and the design freedom for circuit portions, such as wiring within the core portion (100), can be enhanced.

Specifically, the core section provided as a single layer by the prior art has a thicker thickness. Consequently, when machining via holes for the placement of via electrodes, mechanical drilling must be employed. When using mechanical drilling, it is difficult to narrow the gap (spacing) between via holes, the process time required by mechanical drilling increases, and expensive process costs are incurred. Furthermore, when placing via electrodes within the via holes of the single-layer core portion via a plating process, it is difficult to fill the entire via hole. Consequently, a metal layer of a predetermined thickness is only deposited horizontally on the inner walls of the via holes. This imposes limitations on improving mechanical and/or electrical characteristics such as heat dissipation, power transmission, electrical signal transmission, insertion loss, and resistance.

According to the embodiment, by implementing the core portion (100) through multiple insulating layers stacked vertically, compared to a structure where the core portion is implemented as a single layer, not only mechanical drilling but also laser processing of via holes can be performed on the relatively thin individual insulating layers. This reduces manufacturing costs and facilitates the complete filling of the via holes with metal. Furthermore, forming the core portion (100) with a structure where multiple insulating layers are vertically stacked increases design freedom regarding the formation of wiring and via electrodes, thereby offering the advantage of potentially improving production efficiency.

Meanwhile, to prevent deterioration in the bending characteristics of the circuit board (10) compared to a single-layer core portion, each insulating layer constituting the core portion (100) may comprise, as described above, a resin and a reinforcing material, such as glass fibers disposed within the resin.

The circuit board (10) may comprise an upper build-up structure (200) and a lower build-up structure (300). With respect to the core portion (100), the upper build-up structure (200) may be disposed on top of the core portion (100), and the lower build-up structure (300) may be disposed on the lower surface of the core portion (100).

The upper build-up structure (200) may include an upper build-up insulating portion. The upper build-up insulating portion may comprise multiple insulating layers (210) stacked along a vertical direction. The multiple insulating layers (210) of the upper build-up insulating portion may be stacked along the vertical direction on top of the core portion (100). The lowermost insulating layer among the multiple insulating layers (210) constituting the upper build-up insulating portion may be disposed on the second core layer (150). The number of multiple insulating layers (210) constituting the upper build-up insulating portion may be greater than the number of second core layers (150).

The lower build-up structure (300) may comprise a lower build-up insulating portion. The lower build-up insulating portion may comprise a plurality of insulating layers (310) stacked along a vertical direction. The multiple insulating layers (310) of the lower build-up insulating portion may be stacked along the vertical direction from the lower surface of the core portion (100). The uppermost insulating layer among the multiple insulating layers (310) constituting the lower build-up insulating portion may be disposed on the lower surface of the second core layer (150).

Each of the multiple insulating layers (210) of the upper build-up insulating portion and each of the multiple insulating layers (310) of the lower build-up insulating portion may be any insulating material, such as a photo-curable and/or thermosetting material. Thermosetting insulating materials may include insulating materials with inorganic and/or organic fillers dispersed within a resin, such as ABF (Ajinomoto Build-up Film), a product released by Ajinomoto Co., Inc., and prepregs (PPG) containing glass fibers within the resin. Furthermore, the aforementioned resins may exemplarily be epoxy resin, bis-maleimide triazine resin (BT resin), phenolic resin, etc., and the inorganic and/or organic fillers may be provided by materials such as silica, plastics, etc. At least one of the plurality of insulating layers (210) of the upper build-up insulating portion or at least one of the plurality of insulating layers (310) of the lower build-up insulating portion may be a photo-curable insulator, and if it is a photo-curable insulator, it may be a PID (Photo Imageable Dielectric).

In particular, as the core portion (100) is implemented with multiple insulating layers, the durability of the circuit board (10) against bending can be further enhanced when each of the multiple insulating layers (210) of the upper build-up insulating portion and the multiple insulating layers (310) of the lower build-up insulating portion is implemented using prepreg (PPG). Accordingly, the following description shall illustrate, by way of example, the multiple insulating layers (210) of the upper build-up insulating portion and the multiple insulating layers (310) of the lower build-up insulating portion each being prepreg (PPG).

When the multiple insulating layers (210) of the upper build-up insulating portion and the multiple insulating layers (310) of the lower build-up insulating portion are prepreg (Prepreg, PPG), glass fibers may be disposed within the resin constituting the multiple insulating layers (210) of the upper build-up insulating portion and the multiple insulating layers (310) of the lower build-up insulating portion.

The thickness of each of the multiple insulating layers (210) of the upper build-up insulating portion and the multiple insulating layers (310) of the lower build-up insulating portion may be less than the thickness of the first core layer (110) and/or the second core layer (150). Accordingly, the plurality of insulating layers (210) of the upper build-up insulating portion and the plurality of insulating layers (310) of the lower build-up insulating portion may each be provided with via electrodes (230) smaller than the via electrodes (130, 170) disposed within the core portion (100). Consequently, finer wiring than the via electrodes (130, 170) or wiring patterns disposed within the core portion (100) may be disposed in the plurality of insulating layers (210) of the upper build-up insulating portion and the plurality of insulating layers (310) of the lower build-up insulating portion.

Specifically, with respect to the vertical direction, the thickness (H7, see FIG. 2) of each of the multiple insulating layers (210) of the upper build-up insulating portion and the multiple insulating layers (310) of the lower build-up insulating portion may be thinner than the thickness (H2) of the second core layer (150). The thickness (H7) of each of the multiple insulating layers (210) of the upper build-up insulating portion and the multiple insulating layers (310) of the lower build-up insulating portion may be between 30 μm and 45 μm to ensure vertical directional insulation and to accommodate the placement of fine wiring and via electrodes. Accordingly, the ratio of the thickness (H2) of the second core layer (150) to the thickness (H7) of each of the multiple insulating layers (210) of the upper build-up insulating portion and the multiple insulating layers (310) of the lower build-up insulating portion may be 10:3 to 5:4.

Should the ratio of the thickness of each of the multiple insulating layers (210) of the upper build-up insulating portion and the multiple insulating layers (310) of the lower build-up insulating portion to that of the second core layer (150) be less than 10:3, delamination may occur due to stress applied to the insulating layers forming the upper build-up structure (200) and the lower build-up structure (300).

Where the ratio of the thicknesses of the plurality of insulating layers (210) in the upper build-up insulating portion to those of the plurality of insulating layers (310) in the lower build-up insulating portion exceeds 5:4 relative to the second core layer (150), patterns having gap and widths similar to those of the via electrodes (130, 170) and/or wiring may be disposed within the core portion (100). (130, 170) and/or patterns having gap and width similar to those of the wiring may be disposed. That is, difficulties may arise in placing fine patterns, which not only reduces the design freedom of the wiring but also necessitates a significant increase in the overall size and thickness of the circuit board (10), potentially causing delamination and/or warping issues. Furthermore, when electrically connecting to semiconductor devices, the wiring for impedance matching or for transmitting signals or power may differ significantly from the terminals of the semiconductor devices, potentially making close connection between the circuit board (10) and the semiconductor devices difficult.

The core portion (100) may accommodate a circuit portion for electrical signal transmission. The circuit portion may comprise multiple wiring portions disposed within the core portion (100), the upper build-up structure (200), and the lower build-up structure (300), and multiple via electrodes.

The multiple wiring sections may each be disposed on the surface of multiple insulating layers. Here, “disposed on the surface” may also include meaning that at least a portion of the multiple wiring portions is embedded within the multiple insulating layers or protective layers (410, 420) constituting the core portion (100), upper build-up structure (200), and lower build-up structure (300), respectively, and is exposed externally from the surface. The wiring portion may also be termed a metal portion. Furthermore, the surface of the multiple insulating layers includes a one surface, the other surface, and the side surface between the one and the other surfaces. Here, the one surface of the insulating layer may be understood as the upper surface, and the other surface as the lower surface. The meaning of the wiring portion being disposed on the surface implies that it is disposed on at least one of the one surface, the other surface, or side surface of the multiple insulating layers. The structure may also comprise wiring portions disposed on both the one surface and the other surface of some of the multiple insulating layers, while on other parts of the multiple insulating layers, wiring portions are disposed only on either the one surface or the other surface.

Multiple wiring portions may comprise a first wiring portion (121) disposed on the upper surface of the first core layer (110), a second wiring portion (123) disposed on the lower surface of the first core layer (110), a third wiring portion (160) disposed on the second core layer (150), a fourth wiring portion (220) disposed on the upper build-up insulating portion, and a fifth wiring portion (320) disposed on the lower build-up insulating portion. The first to fifth wiring portions (121, 122, 160, 220, 320) may be disposed to overlap in a mutually perpendicular direction.

The third wiring portion (160) may be disposed on the surface of each insulating layer constituting the second core layer (150). For example, the third wiring portion (160) may be disposed on the upper surface of the second-1 core layer (151), the upper surface of the second-2 core layer (152), the lower surface of the second-3 core layer (153), and the lower surface of the second-4 core layer (154), respectively.

The fourth wiring portion (220) and the fifth wiring portion (320) may each be disposed on the surface of each of the plural insulating layers (210) of the upper build-up insulating portion and the plural insulating layers (310) of the lower build-up insulating portion, respectively.

The via electrode may be a metallic material disposed within a via hole formed in each of a plurality of insulating layers to connect a plurality of wiring portions facing each other in the vertical direction. Here, the via hole penetrates at least a portion of each of the plurality of insulating layers in the vertical direction, and the via electrode may be disposed within the via hole.

The circuit board (10) may include a first via electrode (130). The first via electrode (130) may be disposed to penetrate at least a portion of the first core layer (110). The first via electrode (130) may electrically connect a first wiring portion (121) and a second wiring portion (123).

The first electrode (130) may comprise a first portion (134) whose width progressively narrows as it approaches the upper surface of the first core layer (110) from the lower surface of the first core layer (110), and a second portion (132) disposed on the first portion (134), the width of which progressively narrows as it approaches the lower surface of the first core layer (110) from the upper surface of the first core layer (110). As illustrated in FIG. 2, with respect to the second core layer (150) disposed on the first core layer (110), the first portion (134) may have a shape where its horizontal width increases from the second core layer (150) towards the first core layer (110), and the second portion (132) may have a shape where its horizontal width decreases from the second core layer (150) towards the first core layer (110).

The first portion (134) and the second portion (132) may be disposed vertically adjacent to one another. The first portion (134) and the second portion (132) may be formed integrally. The lower end of the first portion (134) may be connected to the second wiring portion (123). The upper end of the second portion (132) may be connected to the first wiring portion (121). The vertical cross-section of the first via electrode (150), defined by the first portion (134) and the second portion (132), may have an hourglass shape.

When forming a via hole in the first core layer (110) by laser for placing the first via electrode (150), the laser may be irradiated onto both the upper and lower surfaces of the first core layer (110). At this time, depending on conditions such as positioning precision and laser intensity, the vertical length (H4) of the first portion (134) of the first via electrode (150) and the vertical length (H3) of the second portion (132) may be identical. The region where the first portion (134) and the second portion (132) meet may be the region that divides the vertical length (H1) of the first via electrode (150) into two equal halves. The ratio of the vertical length (H4) of the first portion (134) to the vertical length (H3) of the second portion (132) may be 1:1. However, this is not necessarily limited to this, and depending on the conditions of the aforementioned process, the vertical length (H4) of the first portion (134) and the vertical length (H3) of the second portion (132) may differ from each other.

The second via electrode (170) may be disposed to penetrate at least a portion of the second core layer (150). The second via electrode (170) may electrically connect the first wiring portion (121) and the third wiring portion (160), the second wiring portion (123) and the third wiring portion (160), and a plurality of third wiring portions (160).

Based on the second core layer (150) disposed on the first core layer (110), the second via electrode (170) may include a fourth portion (172) whose width progressively narrows from the upper surface of second core layer (150) towards its lower surface, and a third portion (174) disposed below the fourth portion (172), which progressively widens in width towards the lower surface of the second core layer (150). The third portion (174) may have a shape where its horizontal width widens from the second core layer (150) towards the first core layer (110). The fourth portion (172) may have a shape where its horizontal width decreases from the second core layer (150) towards the first core layer (110). The fourth portion (172) may be disposed on the third portion (174). The fourth portion (172) and the third portion (174) may be disposed vertically adjacent to one another. The fourth portion (172) and the third portion (174) may be formed integrally.

The third portion (174) and the fourth portion (172) may enable the second via electrode (170) to have an hourglass shape with a cross-section that is asymmetrical in the vertical direction. As illustrated in FIG. 2, the vertical direction length (H5) of the fourth portion (172) and the vertical direction length (H6) of the third portion (174) may differ from one another.

For example, the vertical length (H5) of the fourth portion (172) may be longer than the vertical length (H6) of the third portion (174). In the second via electrode (170), the ratio of the vertical length (H5) of the fourth portion (172) and the vertical direction length (H6) of the third part (174) may differ from the ratio of the vertical direction length (H3) of the first region (151) and the vertical direction length (H4) of the second region (152) in the first via electrode (150). For example, the ratio of the vertical length (H5) of the fourth portion (172) to the vertical length (H6) of the third portion (174) in the second via electrode (170) may be 3:2 to 3:1.

With the second core layer (150), disposed above the first core layer (110), as a reference, the via hole into which the second via electrode (170) is disposed can be formed by irradiating a laser from the upper surface of the second core layer (150) towards the lower surface of the second core layer (150). Specifically, as illustrated in FIG. 4, the via hole (180) in which the second via electrode (170) is disposed may include a first region (184) where the third portion (174) is disposed, and a second region (182) disposed on the first region (184) where the fourth portion (172) is disposed. The first region (184) may have a shape in which the horizontal width widens towards the first core layer (110). The second region (182) may have a shape in which the horizontal width narrows towards the first core layer (110).

Based on FIG. 2, depending on the process conditions, the laser irradiated onto the second core layer (150) may cause scattering to occur on the upper surface of the first wiring portion (121), forming a third portion (174) whose width progressively widens. The third portion (174) increases the bonding area between the second via electrode (170) and the first wiring portion (121), thereby improving the bonding strength of the second via electrode (170).

Moreover, when scattering occurring on the upper surface of the first wiring portion (121) by the laser is significant, it becomes difficult to uniformly form the shape of the via hole in the second core layer (150) for placing the second via electrode (170) across the entire circuit board, potentially leading to a low yield.

Therefore, when the second via electrode (170) is completely filled within the via hole of the second core layer (150), it is desirable that the ratio of the vertical length (H5) of the fourth portion (172) of the second via electrode (170) to the vertical length (H6) of the third portion (174) be provided as 3:2 to 3:1. Furthermore, with reference to FIG. 3, the third portion (174) may be disposed below the glass fiber (150a) disposed within the second core layer (150). Consequently, problems such as leakage current or signal loss can be prevented by avoiding excessive exposure of the glass fiber (150a).

According to the embodiment, the ratio of the vertical direction lengths of the first portion (134) and the second portion (132) within the first via electrode (130) differs from the ratio of the vertical direction lengths of the third portion (174) and the fourth portion (172) within the second via electrode (170). Furthermore, the third via electrode (230) of the upper build-up insulating portion and the lower build-up insulating portion, described below, may include only a region where the width decreases from the upper surface towards the lower surface, but is not limited thereto.

When the third sub-electrode (230) comprises a sixth portion with a horizontally narrowing width and a fifth portion disposed below the sixth portion and also having a horizontally narrowing width towards the second core layer (150), the first ratio of the vertical length of the first portion (134) of the first via electrode (150) to the vertical length of the second portion (132), the second ratio of the vertical length of the third portion (174) of the second via electrode (170) to the vertical length of the fourth portion (172), and the third ratio of the vertical length of the fifth portion of the third via electrode (230) to the vertical length of the sixth portion may differ from one another. Here, each ratio is based on the second portion (132), the fourth portion (172), and the sixth portion, which progressively narrow in width from the upper surface towards the lower surface. The first ratio may be greater than the second ratio, and the second ratio may be greater than the third ratio. For example, the aforementioned ratios may vary depending on the differing thicknesses of the core portion (100), the multiple insulating layers (210) constituting the upper build-up insulating portion, and the multiple insulating layers (310) constituting the lower build-up insulating portion. Consequently, the differences in the aforementioned first to third ratios can mitigate stresses applied to the upper and/or lower portions of the circuit board (10), can have the effect of suppressing warping of the circuit board (10), and can have the effect of improving the integration density and design freedom of wiring for connecting to electronic components such as semiconductor devices.

In particular, by making the first ratio and the second ratio different, warping occurring during the formation process of the core portion (100) is prevented, and it is possible to arrange wiring on the second core layer (150) to have a wiring density between the wiring density of the insulating layers (210, 310) constituting the upper and lower build-up insulating portions and the wiring density of the first core layer (110), thereby facilitating control of impedance matching, insertion loss, etc.

Furthermore, it has the effect of reducing the process cost for forming the via electrodes disposed on each core portion (100) and the insulating layers (210, 310) constituting the upper and lower build-up insulating portions, and increasing the yield. Here, density or integration density refers to the width and gap of wiring or via electrodes; high density is equivalent to high integration density, which should be understood as meaning that the width and/or gap of the wiring and/or the width and/or gap of the via electrodes are small.

Meanwhile, the shape and structure of the aforementioned second via electrode (170) are described using the example of the second via electrode (170) disposed within the second core layer (150) disposed on the first core layer (110). The second via electrode (170) disposed within the second core layer (150) disposed beneath the first core layer (110) may have a shape wherein the third portion (174) and the fourth portion (172) are inverted vertically relative to the aforementioned structure. Accordingly, the second via electrode (170) within the second core layer (150) disposed beneath the first core layer (110) may comprise a third portion (174) and a fourth portion (172), wherein the third portion (174) has a width that progressively widens, and the fourth portion (172) has a vertical length that progressively shortens. The vertical length of the fourth portion (172) may be longer than the vertical length of the third portion (174).

In summary, the second via electrodes (170) disposed in a plurality of second core layers (150) disposed symmetrically in the vertical direction relative to the first core layer (110) may be symmetrical in the vertical direction relative to the first core layer (110).

As shown in FIGS. 1 to 3, the second bias electrode (170) may be disposed to overlap perpendicularly with the first bias electrode (130). This minimizes the signal transmission length within the core portion (100).

The width of the second via electrode (170) may be smaller than the width of the first via electrode (130). This accounts for the relatively greater thickness of the first core layer (110) compared to the second core layer (150). By forming the first via electrode (130) within the relatively thicker first core layer (110) with a larger width, the resistance associated with signal transmission can be minimized.

Meanwhile, at least a portion of the first via electrode (130) may have a smaller width than the second via electrode (170). Specifically, the first via electrode (130) may have a minimum width in the horizontal direction in the region where the first portion (134) and the second portion (132) are in contact. In this case, the maximum width in the horizontal direction of the region disposed above or below the second via electrode (170) may be greater than the minimum width of the first via electrode (130). Consequently, the amount of plating required to form the first via electrode (130) disposed within the first core layer (110) can be reduced.

However, this is not intended to be limiting, and the minimum width in the horizontal direction at the region where the first portion (134) and the second portion (132) of the first via electrode (130) contact may be greater than the maximum width in the horizontal direction of the second via electrode (170).

The third via electrode (230) may be disposed to penetrate each of the multiple insulating layers (210) of the upper build-up insulating portion. The fourth via electrode (330) may be disposed to penetrate each of the multiple insulating layers (310) of the lower build-up insulating portion. The third via electrode (230) and the fourth via electrode (330) may have a structure inverted in the vertical direction relative to the core portion (100). Therefore, hereinafter, the via electrodes disposed in the upper and lower build-up structures shall be described with reference to the third via electrode (230) disposed in each of the multiple insulating layers (210) constituting the upper build-up insulating portion.

The third via electrode (230) may electrically connect a plurality of fourth wiring portions (220) disposed in the vertical direction with the fourth wiring portion (220) and the third wiring portion (160).

The third via electrode (230) may electrically connect the fourth wiring portion (220) and the pad portion disposed on the upper build-up insulating portion.

The third via electrode (230) may have a shape wherein its width progressively narrows from the upper surface of the insulating layer (210) constituting the upper build-up insulating portion towards the lower surface of the insulating layer (210). The fourth via electrode (330) may have a shape wherein its horizontal width progressively narrows as it moves from the lower surface of the insulating layer (310) constituting the lower build-up insulating portion towards the upper surface of the insulating layer (310).

The width of the second via electrode (170) may be greater than the width of the third via electrode (230). This accounts for the fact that the second core layer (150) has a relatively greater thickness than the insulating layer (210) constituting the upper build-up insulating portion. Consequently, the signal transmission resistance in the second via electrode (170) disposed within the core portion (100) can be minimized.

Although not explicitly illustrated, based on the single fourth wiring portion (220), the third via electrode (230) connected to the fourth wiring portion (220) may comprise a plurality of elements. This enables an improvement in signal transmission efficiency.

As illustrated in FIG. 1, the circuit board (10) according to the embodiment may comprise a first wiring portion (121), a second wiring portion (123), a third wiring portion (160), a fourth wiring portion (220), a fifth wiring portion (320), a first via electrode (130), a second via electrode (170), a third via electrode (230), and a fourth via electrode (330) disposed in a vertically stacked configuration. Consequently, the vertical signal path within the circuit board (10) is reduced, thereby improving signal transmission efficiency.

In semiconductor packages applied to recent AI, Cloud, and autonomous driving fields, package size is increasing due to the demand for high integration to achieve high performance. Consequently, there is a growing need for stacked vias-a structure where via electrodes are vertically stacked and interconnected between as many insulating layers as possible-either to reduce the number of insulating layers constituting the circuit board or to minimize signal paths.

However, with circuit boards according to conventional technology, as the thickness of the core portion increases to suppress board warping, the via hole processing method is constrained to mechanical drilling, presenting the problem that it is difficult to reduce the size of the via electrode within the core portion. Furthermore, the increased thickness of the core portion and the increased width of the via electrode also lead to increased stress applied to the via electrode disposed within the upper and lower build-up structures. Consequently, the problem is that the number of insulating layers constituting the upper and lower build-up structures must also be increased.

According to the embodiment, by implementing the core portion (100) through multiple insulating layers comprising a first core layer (110) and a second core layer (150), the formation process of the via electrodes (130, 170) provided in each core layer can be more readily accomplished compared to a conventional single core layer. Furthermore, as one moves from the vertically centered first core layer (110) towards the surface of the circuit board (10), the horizontal width of the via electrodes (130, 170, 230, 330) gradually decrease in horizontal width. This enables the stresses arising from the vertical overlapping structure of the multiple via electrodes to be uniformly dispersed. That is, as the horizontal width of the second via electrode (170) disposed within the second core layer (150) is formed to be smaller than the horizontal width of the first via electrode (130) and larger than the horizontal width of the third via electrode (230), the vertical arrangement of the plurality of via electrodes can be more readily implemented.

The circuit board (10) may comprise protective layers (410, 420). The protective layers (410, 420) may include a first protective layer (410) disposed on the surface of the upper build-up structure (200) and a second protective layer (420) disposed on the surface of the lower build-up structure (300). The first protective layer (410) and the second protective layer (420) can perform the function of preventing short circuits between solder when semiconductor devices are disposed on the surface of the circuit board (10) using materials such as solder, due to low wettability with the solder. They can also prevent the problem of external contaminants penetrating into the build-up structure and degrading reliability. The first protective layer (410) and the second protective layer (420) may each utilize a light-curable insulating material. Therefore, the first protective layer (410) and the second protective layer (420) are provided as solder resist, not the aforementioned ABF, PPG, BT resin, or PID. However, this is not limited to this, and as described above, they may be provided with various materials capable of performing the function of preventing solder-to-solder short circuits due to low wettability with solder.

The first protective layer (410) may include holes to expose pad portions disposed on the surface of the upper build-up structure (200) upwards. Connection members (415), such as solder balls, may be disposed in the holes. The second protective layer (420) may include holes to expose pad portions disposed on the surface of the lower build-up structure (300) to the underside of the circuit board (10).

Accordingly, the circuit board (10) may implement a semiconductor package together with a semiconductor chip coupled via the connection member (415).

Hereinafter, the arrangement structure of the circuit portion and each insulating layer according to an embodiment of the present invention shall be described.

The insulating layer described below may be any one of the first core layer (110), the second core layer (150), the plural insulating layers (210) of the upper build-up insulating portion, or the plural insulating layers (310) of the lower build-up insulating portion within the aforementioned circuit board (10).

The circuit portion described below may be any one of the multiple wiring portions disposed on the aforementioned circuit board (10), but this does not exclude the possibility of it being any one of the multiple via electrodes.

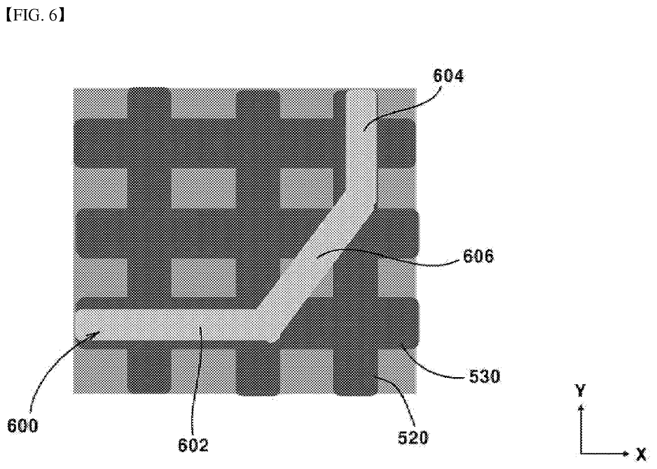

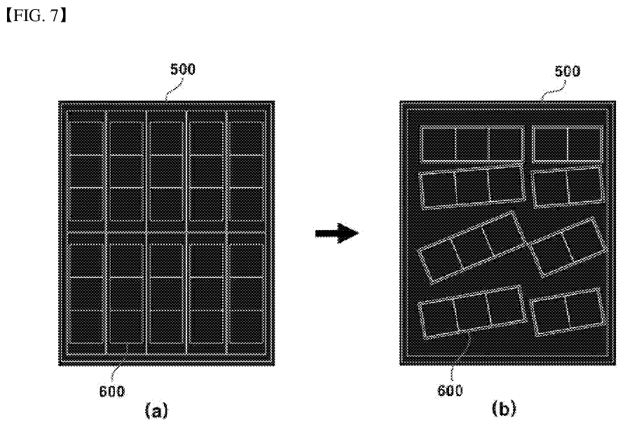

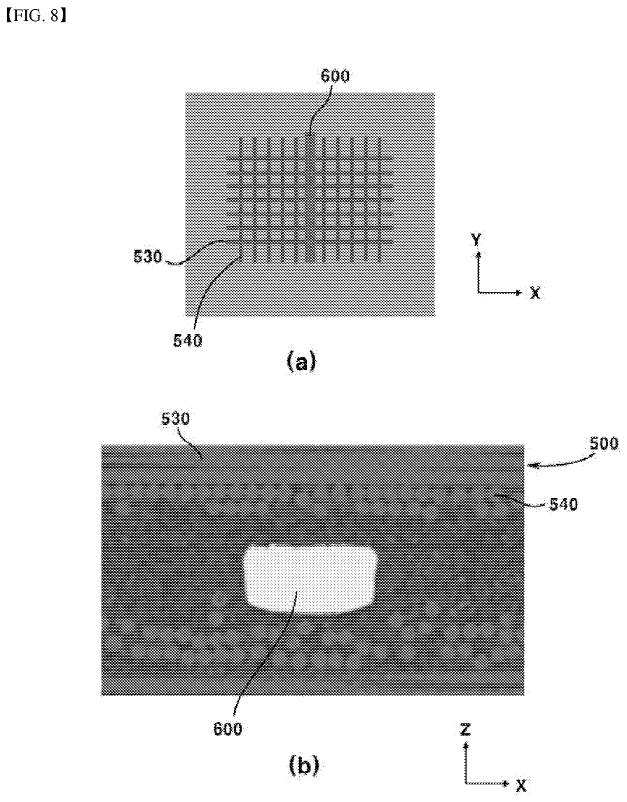

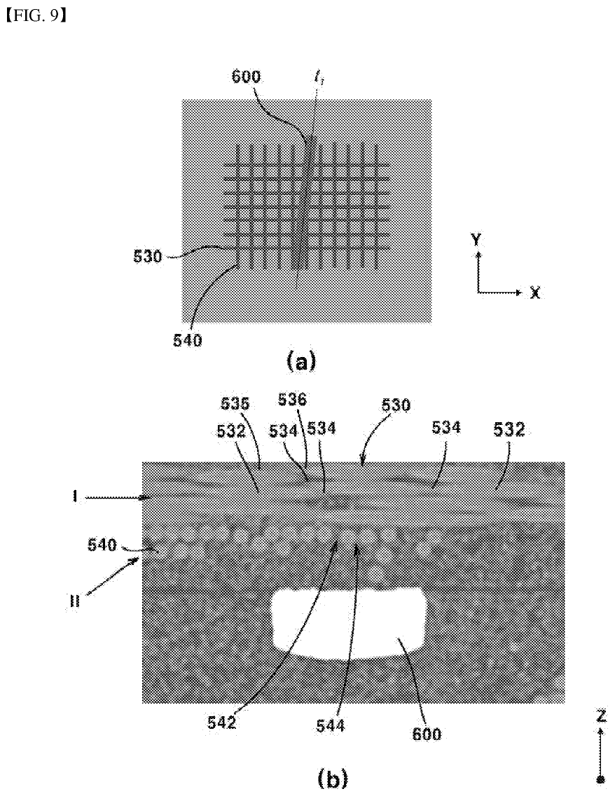

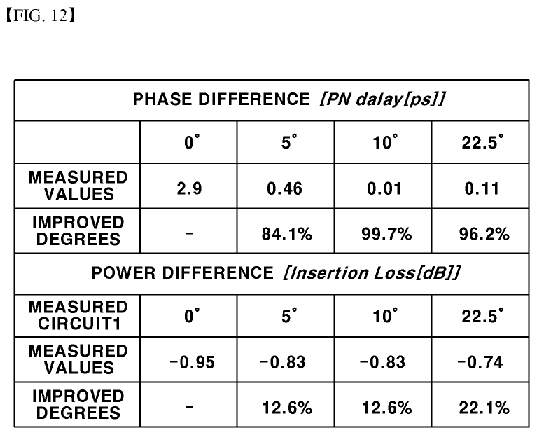

FIG. 5 is an illustration showing the arrangement structure of glass fibers within the insulating layer according to an embodiment of the present invention, FIGS. 6 and 7 are illustrations for explaining signal loss according to the arrangement structure of glass fibers and circuit portions, FIG. 8 is a diagram illustrating the arrangement structure of glass fibers and circuitry according to a comparative example, FIGS. 9 to 11 are various diagrams illustrating the arrangement structure of glass fibers and circuitry according to embodiments of the present invention, and FIG. 12 is a table comparing signal loss between a circuit board according to a comparative example and a circuit board according to an embodiment of the present invention.

Referring to FIGS. 5 to 12, a circuit board according to an embodiment of the present invention may comprise an insulating layer (500) and a circuit portion (600).

The insulating layer (500) may comprise a resin (510) and glass fibers (520) disposed within the resin (510). The insulating layer (500) may be a prepreg (PPG) wherein the resin (510) is impregnated into the glass fibers (520). For example, the resin (510) may comprise at least one of epoxy, polyimide, and bis-maleimide. The glass fibers (520), acting as a reinforcing material, enhance the durability of the insulating layer (500), thereby improving the bending characteristics of the circuit board (10).

Furthermore, although not shown, the insulating layer (500) may include a filler as a reinforcing material in addition to the glass fibers (520). The filler may be composed of organic or inorganic material.

The glass fiber (520) may comprise a first glass fiber (530) extending in a first horizontal direction (X) and a second glass fiber (540) extending in a second horizontal direction (Y) perpendicular to the first horizontal direction (X). The first glass fiber (530) and the second glass fiber (540) may be disposed in a mutually orthogonal configuration.

As illustrated in FIGS. 9 to 11, the first glass fiber (530) and the second glass fiber (540) may be provided in a form where the warp and weft are woven. However, this is not limiting, and the first glass fiber (530) and the second glass fiber (540) may also be disposed within the resin (510) in a mutually partitioned form along the vertical direction. In this case, the first glass fiber (530) may be disposed on top of the second glass fiber (540).

The circuit portion (600) may be disposed on the surface of the insulating layer (500). For example, the circuit portion (600) may be disposed on the insulating layer (500) and may be electrically connected to circuit portion disposed on another insulating layer. Furthermore, the circuit portion (600) may also have an ETS (Embedded Trace Substrate) structure to implement fine patterns. In this case, the circuit portion (600) may be embedded within the insulating layer (500). Here, “embedded” means that at least part of the side of the circuit portion (600) having the ETS structure is covered by the insulating layer (500).

The insulating layer (500) may include a recess for embedding the circuit portion (600).

The circuit portion (600) may be disposed to form lines along a horizontal direction on the surface of the insulating layer (500). FIG. 6 is intended to illustrate the signal transmission efficiency according to the arrangement of the circuit portion and glass fibers. Referring to FIG. 6, when the circuit portion (600) comprises a first region (602), a second region (604), and a third region (606), wherein the first region (602) has a longitudinal direction along a first horizontal direction (X) which is the extension direction of the first glass fiber (530), the second region (604) has a longitudinal direction along a second horizontal direction (Y) which is the extension direction of the second glass fiber (540), and the third region (606) may be disposed at an inclination relative to a virtual axis forming the first horizontal direction (X) or the second horizontal direction (Y), such that it forms a predetermined angle with either the first region (602) or the second region (604). In this case, the first region (602) may overlap perpendicularly with the first glass fiber (530), and the second glass fiber (604) may overlap perpendicularly with the second glass fiber (540). Furthermore, the third region (606) may have a relatively smaller area overlapping with the glass fibers (520) in a direction perpendicular to them, compared to the first region (602) and the second region (604).

Here, the meaning of “small area” may refer to the distribution of the vertical overlap area with the glass fiber (520) per unit area.

In the arrangement of the circuit portion (600) depicted in FIG. 6, for the first region (602) and the second region (604), signal transmission through these regions to other circuit portions suffers loss due to the vertically overlapping structure with the glass fiber (520). However, in the case of the third region (606), since at least a portion is misalignedly disposed in a direction perpendicular to the glass fibers (520), the signal transmission loss through the third region (606) to other circuit portions is relatively small.

Considering this, the circuit board according to the embodiment is characterized in that, as shown in FIG. 7(b), the arrangement of the circuit portion (600) is tilted relative to the extension direction of the glass fiber (520), thereby minimizing the vertical overlapping area with the glass fiber (520) and minimizing signal transmission loss in the circuit portion (600).

Referring to FIG. 7(a) and 8, the circuit board according to the comparative example may be disposed such that the circuit portion (600) overlaps with the first glass fiber (530) or the second glass fiber (540) in the vertical direction (Z). Specifically, the longitudinal direction of the circuit portion (600) may be identical to the extension direction of either the first glass fiber (530) or the second glass fiber (540). By way of example, the circuit portion (600) may be disposed such that its longitudinal direction is aligned with the second horizontal direction (Y), which is the extension direction of the second glass fiber (540). Consequently, the circuit portion (600) may be disposed such that it overlaps with the second glass fiber (540) in the vertical direction (Z).

In this case, as shown in FIG. 8(b), based on a cross-section perpendicular to the longitudinal direction of the circuit portion (600), the first glass fiber (530) may be formed such that its vertical direction (Z) width remains constant along the horizontal direction. That is, since the circuit portion (600) is disposed to overlap the first glass fiber (530) extended in the second horizontal direction (Y) in the vertical direction (Z), the first glass fiber (530) can be formed such that its vertical (Z) width is uniform along the horizontal direction, based on a cross-section perpendicular to the longitudinal direction of the circuit portion (600). Meanwhile, in a cross-section perpendicular to the longitudinal direction of the circuit portion (600), each of the plurality of second glass fibers (540) may be disposed horizontally such that a constant gap is formed with an adjacent second glass fiber (540) along the horizontal direction.

FIG. 9 is a diagram illustrating a structure wherein the circuit portion (600) is tilted on the insulating layer (500) such that the length direction (l1) of the circuit portion (600) forms a first angle relative to the extension direction (Y) of the second glass fibers (540). The first angle may be 5 degrees.

Referring to FIG. 9, the longitudinal direction (l1) of the circuit portion (600) may form an angle of 5 degrees with respect to an imaginary axis parallel to the longitudinal direction (Y) of the second glass fiber (540). Accordingly, the circuit portion (600) may be disposed such that at least a portion thereof is misaligned with the second glass fiber (540) in the vertical direction (Z).

In this case, as shown in FIG. 9(b), the cross-section of the circuit portion (600) may include the cross-section of the first glass fiber (530) and the cross-section of the second glass fiber (540). Specifically, based on a cross-section perpendicular to the longitudinal direction (l1) of the circuit portion (600), the first glass fiber (530) may comprise multiple regions having different widths in the vertical direction (Z).

Specifically, based on a cross-section perpendicular to the lengthwise direction (l1) of the circuit portion (600), the first glass fiber (530) may comprise multiple regions with varying thicknesses in the vertical direction, disposed along the third horizontal direction. Here, the third horizontal direction may be the horizontal direction defined with respect to FIG. 9(b), which is perpendicular to the longitudinal direction (l1) of the circuit portion (600). Specifically, the first glass fiber (530) may include a first region (532) with a large vertical (Z) width and a second region (534) with a relatively small vertical (Z) width. The vertical direction (Z) width of the first glass fiber (530) may progressively decrease from the first region (532) towards the second region (534), and may progressively increase from the second region (534) towards the first region (532). The first region (532) and the second region (534) may be disposed alternately along the horizontal direction of the cross-section of the circuit portion (600). This results from positioning the circuit portion (600) at a predetermined tilt angle relative to the glass fiber (520). Compared to the comparative example shown in FIG. 8, it signifies that the cross-section perpendicular to the longitudinal direction (l1) of the circuit portion (600) and the cross-section along the longitudinal direction of the first glass fiber (530) are different from each other.

In some instances, the first glass fiber (530) may possess horizontally separated regions, based on a cross-section perpendicular to the length direction (l1) of the circuit portion (600). These separated regions may be disposed between a plurality of first regions (532).

Moreover, in a cross-section perpendicular to the longitudinal direction (l1) of the circuit portion (600), the second glass fiber (540) may comprise multiple regions where the thickness in the vertical direction (z) varies. The multiple regions of the second glass fiber (540) may be disposed along the third horizontal direction.

In a cross-section perpendicular to the longitudinal direction (l1) of the circuit portion (600), the plurality of second glass fibers (540) may be disposed such that each forms a different gap from an adjacent second glass fiber (540) along the horizontal direction. For example, when three (3) second glass fibers (540) sequentially disposed along the horizontal direction are designated as second-1 glass fiber, second-2 glass fiber, and second-3 glass fiber, based on a cross-section perpendicular to the lengthwise direction (l1) of the circuit portion (600), the second-1 glass fiber and the second-2 glass fiber may be disposed to form a first gap (542) in the horizontal direction, and the second-2 glass fiber and the second-3 glass fiber may be disposed to form a second gap (544) in the horizontal direction, which is different from the first gap (542). This results from arranging the circuit portion (600) at a predetermined tilt angle relative to the glass fibers (520). Compared to the comparative example shown in FIG. 8, this means that the cross-section perpendicular to the length direction (l1) of the circuit portion (600) differs from the cross-section perpendicular to the length direction of the second glass fiber (540).

From a more diverse perspective, based on a cross-section perpendicular to the longitudinal direction (l1) of the circuit portion (600), the glass fibers (520) may comprise first glass fibers (530) forming a first group (I) and second glass fibers (540) forming a second group (II). The first group (I) and the second group (II) may be disposed along the vertical direction of the circuit board (10). The first glass fibers (530) constituting the first group (I) may each include a convex portion (535). The convex portions (535) may be provided in plurality and disposed horizontally in a cross-section perpendicular to the lengthwise direction (l1) of the circuit portion (600). Between the plural convex portions (535), concave portions (536) with relatively small vertical widths may be disposed. The plural convex portions (535) may be connected horizontally via the concave portions (536). In some instances, based on a cross-section perpendicular to the longitudinal direction (l1) of the circuit portion (600), separated regions, horizontally separated between the plural convex portions (535), may be disposed.

Based on a cross-section perpendicular to the longitudinal direction (l1) of the circuit section (600), the second glass fibers (540) constituting the second group (II) may each have a circular or elliptical cross-sectional shape. In this case, with respect to a cross-section perpendicular to the longitudinal direction (l1) of the circuit portion (600), the gap between adjacent second glass fibers (540) may be varied.

The aforementioned structure results from arranging the circuit portion (600) at a predetermined tilt angle relative to the glass fiber (520), meaning that the cross-section perpendicular to the lengthwise direction (l1) of the circuit portion (600) differs from the cross-section perpendicular to the lengthwise direction of the first glass fiber (530) or the second glass fiber (540).

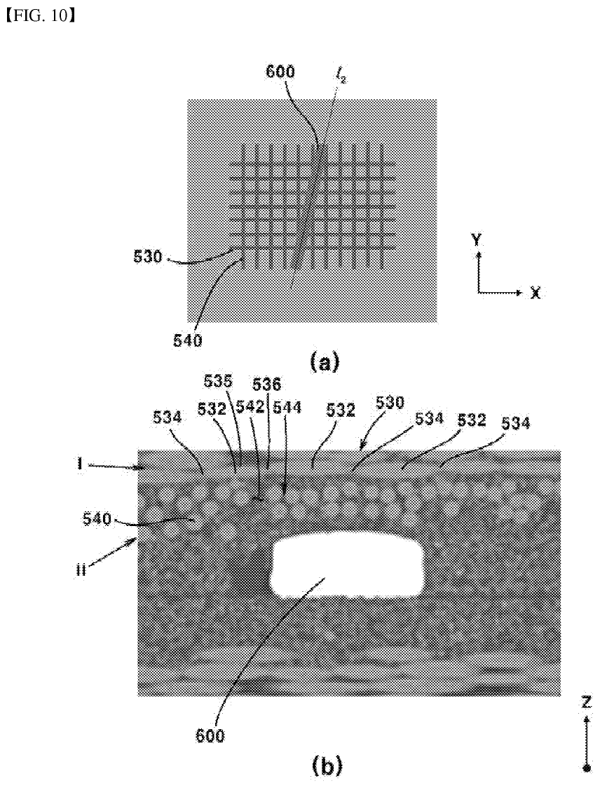

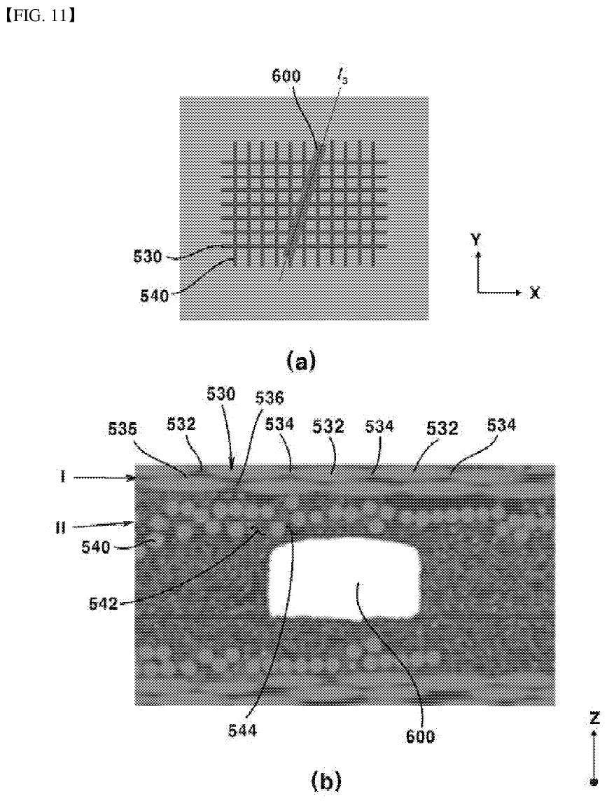

FIG. 10 is a diagram illustrating a structure wherein the circuit portion (600) is tilted on the insulating layer (500) such that the longitudinal direction (l2) of the circuit portion (600) forms a second angle greater than the first angle relative to the extension direction (Y) of the second glass fiber (540). The second angle may be 10 degrees.

Referring to FIG. 10, the longitudinal direction (l2) of the circuit portion (600) may form an angle of 10 degrees relative to an imaginary axis parallel to the longitudinal direction (Y) of the second glass fiber (540). Accordingly, the circuit portion (600) may be disposed such that at least a portion thereof is misaligned with the second glass fiber (540) in the vertical direction (Z). In this case, the area of the circuit portion (600) misaligned with the second glass fiber (540) in the vertical direction (Z) may be larger than when the circuit portion (600) is tilted by the first angle.

As shown in FIG. 10(b), the cross-section of the circuit portion (600) may comprise the cross-section of the first glass fiber (530) and the cross-section of the second glass fiber (540). Specifically, based on a cross-section perpendicular to the longitudinal direction (l2) of the circuit portion (600), the first glass fiber (530) may comprise multiple regions having different widths in the vertical direction (Z).

Specifically, based on a cross-section perpendicular to the lengthwise direction (l2) of the circuit portion (600), the first glass fiber (530) may comprise a plurality of regions having different thicknesses in the vertical direction (Z) disposed along the third horizontal direction. That is, based on a cross-section perpendicular to the longitudinal direction (l2) of the circuit portion (600), the first glass fiber (530) may comprise a first region (532) with a large vertical (Z) width and a second region (534) with a relatively small vertical (Z) width. The vertical (Z) width of the first glass fiber (530) may progressively decrease from the first region (532) towards the second region (534), and may progressively increase from the second region (534) towards the first region (532). The first region (532) and the second region (534) may be disposed alternately along the horizontal direction of the cross-section of the circuit portion (600). This results from arranging the circuit section (600) at a predetermined tilt angle relative to the glass fiber (520). Compared to the comparative example shown in FIG. 8, this means that the cross-section perpendicular to the longitudinal direction (l2) of the circuit portion (600) and the cross-section along the longitudinal direction of the first glass fiber (530) are different.

In certain instances, based on a cross-section perpendicular to the longitudinal direction (l₂) of the circuit portion (600), the first glass fiber (530) may possess horizontally separated regions. These separated regions may be disposed between multiple first regions (532).

Meanwhile, when compared to a structure where the circuit portion (600) is tilted at a relatively small first angle, the horizontal length between multiple first regions (532) in the vertical cross-section of the circuit portion (600) tilted at the second angle may be shorter than the horizontal length between multiple second regions (534).

Moreover, in a cross-section perpendicular to the lengthwise direction (l₂) of the circuit portion (600), the second glass fiber (540) may comprise multiple regions where the thickness in the vertical direction (z) varies. The multiple regions of the second glass fiber (540) may be disposed along the third horizontal direction.

In a cross-section perpendicular to the longitudinal direction (l2) of the circuit portion (600), the plurality of second glass fibers (540) may be disposed such that each forms a different gap relative to an adjacent second glass fiber (540) along the horizontal direction. For example, when three (3) second glass fibers (540) sequentially disposed along the horizontal direction are designated as second-1 glass fiber, second-2 glass fiber, and second-3 glass fiber, based on a cross-section perpendicular to the lengthwise direction (l2) of the circuit portion (600), the second-1 glass fiber and the second-2 glass fiber may be disposed to form a first gap (542) in the horizontal direction, and the second-2 glass fiber and the second-3 glass fiber may be disposed to form a second gap (544) in the horizontal direction, which is different from the first gap (542). This results from arranging the circuit portion (600) at a predetermined tilt angle relative to the glass fiber (520). Compared to the comparative example shown in FIG. 8, this means that the cross-section perpendicular to the length direction (l2) of the circuit portion (600) differs from the cross-section perpendicular to the length direction of the second glass fiber (540).

Meanwhile, when compared to a structure where the circuit portion (600) is tilted at a relatively small first angle, the gap between adjacent plural second glass fibers (540) in the vertical cross-section of the circuit portion (600) tilted at the second angle may be longer.

From a broader perspective, based on a cross-section perpendicular to the longitudinal direction (l1) of the circuit portion (600), the glass fibers (520) may comprise first glass fibers (530) forming a first group (I) and second glass fibers (540) forming a second group (II). The first group (I) and the second group (II) may be disposed along the vertical direction of the circuit board (10). The first glass fibers (530) constituting the first group (I) may each include a convex portion (535).

The convex portions (535) are provided in plurality and may be disposed horizontally along a cross-section perpendicular to the longitudinal direction (l1) of the circuit portion (600). Between the plural convex portions (535), concave portions (536) with relatively small vertical widths may be disposed. The plural convex portions (535) may be connected horizontally via the concave portions (536). In some instances, based on a cross-section perpendicular to the longitudinal direction (l1) of the circuit portion (600), separated regions may be disposed horizontally between the plural convex portions (535).

Meanwhile, compared to a structure where the circuit portion (600) is tilted at a relatively small first angle, the horizontal distance between the multiple convex portions (535) and the horizontal distance between the multiple concave portions (536) in the vertical cross-section of the circuit portion (600) tilted at the second angle may be shorter.

Based on a cross-section perpendicular to the longitudinal direction (l1) of the circuit portion (600), the second glass fibers (540) constituting the second group (II) may each have a circular or elliptical cross-sectional shape. In this case, with respect to a cross-section perpendicular to the longitudinal direction (l1) of the circuit portion (600), the gap between adjacent second glass fibers (540) may be varied.

The aforementioned structure results from arranging the circuit portion (600) at a predetermined tilt angle relative to the glass fibre (520), meaning that the cross-section perpendicular to the longitudinal direction (l1) of the circuit portion (600) differs from the cross-section perpendicular to the longitudinal direction of the first glass fiber (530) or the second glass fiber (540).

FIG. 11 is a diagram illustrating a structure wherein the circuit portion (600) is tilted on the insulating layer (500) such that the longitudinal direction (l3) of the circuit portion (600) forms a third angle greater than the second angle relative to the extension direction (Y) of the second glass fiber (540). The third angle may be 22.5 degrees.

Referring to FIG. 11, the length direction (l3) of the circuit portion (600) may form an angle of 22.5 degrees with respect to an imaginary axis parallel to the length direction (Y) of the second glass fiber (540). Accordingly, the circuit portion (600) may be disposed such that at least a portion is misaligned with the second glass fiber (540) in the vertical direction (Z). In this case, the area of the circuit portion (600) misaligned with the second glass fiber (540) in the vertical direction (Z) may be larger than when the circuit portion (600) is tilted by the first angle.

As shown in FIG. 11(b), the cross-section of the circuit portion (600) may include the cross-section of the first glass fiber (530) and the cross-section of the second glass fiber (540). Specifically, based on a cross-section perpendicular to the longitudinal direction (l3) of the circuit portion (600), the first glass fiber (530) may comprise multiple regions having different widths in the vertical direction (Z).

Specifically, based on a cross-section perpendicular to the lengthwise direction (l3) of the circuit portion (600), the first glass fiber (530) may comprise multiple regions having differing thicknesses in the vertical direction (Z). That is, based on a cross-section perpendicular to the longitudinal direction (l3) of the circuit portion (600), the first glass fiber (530) may include a first region (532) with a large vertical direction (Z) width and a second region (534) with a relatively small vertical direction (Z) width. The vertical (Z) width of the first glass fiber (530) may progressively decrease from the first region (532) towards the second region (534), and may progressively increase from the second region (534) towards the first region (532). The first region (532) and the second region (534) may be disposed alternately along the horizontal direction of the cross-section of the circuit portion (600). This results from arranging the circuit portion (600) at a predetermined tilt angle relative to the glass fiber (520). Compared to the comparative example shown in FIG. 8, this means that the cross-section perpendicular to the longitudinal direction (l3) of the circuit portion (600) and the cross-section along the longitudinal direction of the first glass fiber (530) are mutually different.

In certain instances, based on a cross-section perpendicular to the longitudinal direction (l3) of the circuit portion (600), the first glass fiber (530) may possess horizontally separated regions. These horizontally separated regions may be disposed between a plurality of first regions (532).

Meanwhile, when compared to a structure where the circuit portion (600) is tilted at a relatively small second angle, the horizontal direction length between multiple first regions (532) and the horizontal direction length between multiple second regions (534) in the vertical direction cross-section of the circuit portion (600) tilted at the third angle may be shorter.

From a more diverse perspective, based on a cross-section perpendicular to the longitudinal direction (l1) of the circuit portion (600), the glass fibers (520) may include first glass fibers (530) forming a first group (I) and second glass fibres (540) forming a second group (II). The first group (I) and the second group (II) may be disposed along the vertical direction of the circuit board (10). The first glass fibers (530) constituting the first group (I) may each include a convex portion (535).

The convex portions (535) are provided in plurality and may be disposed horizontally along a cross-section perpendicular to the longitudinal direction (l1) of the circuit portion (600). Between the plural convex portions (535), concave portions (536) with relatively small vertical widths may be disposed. The plural convex portions (535) may be connected horizontally via the concave portions (536). In some instances, based on a cross-section perpendicular to the longitudinal direction (l1) of the circuit portion (600), separated regions may be disposed horizontally between the plural convex portions (535).

Meanwhile, compared to a structure where the circuit portion (600) is tilted at a relatively small second angle, in the vertical cross-section of the circuit section (600) tilted at the third angle, the horizontal distance between the plurality of convex portions (535) and the horizontal distance between the plurality of concave portions (536) may be shorter.

Moreover, in a cross-section perpendicular to the longitudinal direction (l3) of the circuit portion (600), the second glass fiber (540) may comprise multiple regions with varying thicknesses in the vertical direction (z). The multiple regions of the second glass fiber (540) may be disposed along the third horizontal direction.

Based on a cross-section perpendicular to the longitudinal direction (l1) of the circuit portion (600), the second glass fibers (540) constituting the second group (II) may each have a circular or elliptical cross-sectional shape. In this case, based on a cross-section perpendicular to the longitudinal direction (l1) of the circuit portion (600), the gap between adjacent second glass fibers (540) may be varied.

The aforementioned structure is achieved by arranging the circuit portion (600) at a predetermined tilt angle relative to the glass fiber (520), meaning that a cross-section perpendicular to the longitudinal direction (l1) of the circuit portion (600) differs from a cross-section perpendicular to the longitudinal direction of the first glass fiber (530) or the second glass fiber (540).

Moreover, in a c ross-section perpendicular to the lengthwise direction (l3) of the circuit portion (600), the plurality of second glass fibers (540) may be disposed such that each forms a different gap from an adjacent second glass fiber (540) along the horizontal direction. For example, when three (3) second glass fibers (540) sequentially disposed along the horizontal direction are designated as second-1 glass fiber, second-2 glass fiber, and second-3 glass fiber, based on a cross-section perpendicular to the lengthwise direction (l3) of the circuit portion (600), the second-1 glass fiber and the second-2 glass fiber may be disposed to form a first gap (542) in the horizontal direction, and the second-2 glass fiber and the second-3 glass fiber may be disposed to form a second gap (544) in the horizontal direction, which is different from the first gap (542). This results from the circuit portion (600) being disposed at a predetermined tilt angle relative to the glass fibers (520). When compared to the comparative example shown in FIG. 8, this means that the cross-section perpendicular to the length direction (l3) of the circuit portion (600) differs from the cross-section perpendicular to the length direction of the second glass fiber (540).

Meanwhile, when compared to a structure where the circuit portion (600) is tilted at a relatively small second angle, the gap between adjacent plural second glass fibers (540) in the vertical cross-section of the circuit portion (600) tilted at the third angle may be longer.

FIG. 12 is a table comparing the phase difference and power difference between multiple circuit portions (600) according to an exemplary comparative case where the circuit portion (600) is disposed vertically overlapping the glass fiber (520), and an exemplary case where the circuit portion (600) is tilted at various angles relative to the glass fiber (520). Here, the multiple circuit portions (600) are disposed in a structure that is perpendicular to the insulating layer (500) on which the glass fibers (520) are disposed.

Referring to FIG. 12, according to an embodiment where the circuit portion (600) is disposed to be tilted at a predetermined angle relative to the second glass fiber (540), it can be observed that the phase difference and power difference between the multiple circuit portions (600) are reduced, compared to the comparative example where the circuit portion (600) and the second glass fiber (540) are superimposed in the vertical direction (Z). This indicates that, when comparing the circuit board (10) according to the embodiment with the comparative example, power loss is reduced and electrical signal transmission efficiency is improved in the transmission of electrical signals between the multiple circuit sections (600).

However, when the longitudinal direction of the circuit portion (600) is tilted by 22.5 degrees or more relative to the extension direction of the second glass fiber (540), the phase difference actually increases. Furthermore, as the tilt angle of the circuit portion (600) relative to the glass fiber (520) increases, the placement area of the circuit portion (600) on the insulating layer (500) becomes excessively large, making it difficult to achieve a fine pitch. it is preferable that the longitudinal direction of the circuit portion (600) forms an angle of 5 degrees or more but less than 22.5 degrees relative to an imaginary axis parallel to the longitudinal direction of the first glass fiber (530) or the second glass fiber (540). As shown in the table of FIG. 12, the specific angle may be 10 degrees.

According to the embodiment, by arranging the circuit portion (600) so that it is tilted relative to the glass fiber (520) within the insulating layer (500), the vertically overlapping area between the glass fiber (520) and the circuit portion (600) can be minimized.

Consequently, this offers the advantage of reducing power loss compared to conventional methods and improving signal transmission efficiency for the multiple circuit portions (600) disposed within the circuit board (10).

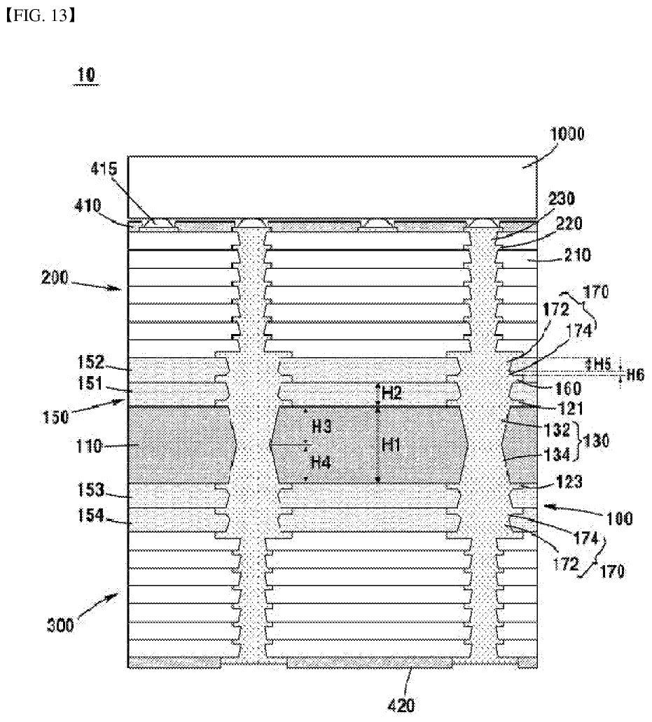

FIG. 13 is a diagram illustrating a semiconductor package according to an embodiment of the present invention.

Referring to FIG. 13, the semiconductor package according to an embodiment of the present invention may include a semiconductor chip (1000) disposed on the circuit board (10). Exemplarily, the semiconductor chip (1000) may be disposed on the upper build-up structure (200). The semiconductor chip (1000) may be electrically and physically coupled to the pad portion disposed on the upper build-up structure (200) via the connection member (415).

The foregoing description of the components constituting the embodiments of the present invention as being combined or operating in combination does not imply that the invention is necessarily limited to these embodiments. That is to say, within the scope of the objectives of the present invention, all components may also be selectively combined and operate in one or more ways. Furthermore, terms such as “include”, “comprise”, or “have” as described above, unless specifically stated otherwise, imply that the component may be present. Therefore, they should be interpreted as meaning that the component may include other components, not that it excludes other components. All terms, including technical or scientific terms, unless otherwise defined, have the same meaning as generally understood by a person skilled in the art to which the invention pertains. Commonly used terms, such as those defined in dictionaries, shall be interpreted in accordance with their meaning in the context of the relevant technology and shall not be interpreted in an idealized or overly formalistic sense unless explicitly defined herein.

The foregoing description merely exemplifies the technical concept of the present invention. Those skilled in the art to which the present invention pertains will appreciate that various modifications and variations may be made without departing from the essential character of the invention. Therefore, the embodiments disclosed herein are intended to illustrate the technical concept of the invention, not to limit it, and the scope of the technical concept of the invention is not restricted by these embodiments. The scope of protection of the invention shall be interpreted by the appended claims, and all technical concepts within the scope equivalent thereto shall be interpreted as falling within the scope of the invention.

Meanwhile, when a circuit board possessing the aforementioned features of the invention is utilized in IT devices or home appliances such as smartphones, server computers, or televisions, it can reliably perform functions such as signal transmission or power supply. For example, when a circuit board possessing the features of the present invention performs a semiconductor package function, it can safely protect the semiconductor chip from external moisture or contaminants, and can resolve issues such as leakage current, electrical short circuits between terminals, or electrical open circuits in the terminals supplying the semiconductor chip. Furthermore, when responsible for signal transmission functions, it can resolve noise issues. Consequently, the circuit board possessing the aforementioned features of the invention enables the stable functioning of IT devices or home appliances, thereby achieving functional integrity or technical interconnectivity between the entire product and the circuit board incorporating the present invention.

When a circuit board possessing the aforementioned invention's features is utilized in transport devices such as vehicles, it can resolve signal distortion issues transmitted to the transport device, or safely protect the semiconductor chip controlling the transport device from external sources. It can also address problems such as leakage current, electrical short circuits between terminals, or electrical open circuits in the terminals supplying the semiconductor chip, thereby further improving the transport device's stability. Therefore, the transport device and the circuit board incorporating the present invention can achieve functional integration or technical interlocking.

1. A circuit board, comprising:
an insulating layer including resin and glass fibers disposed within the resin; and
a circuit portion disposed on the insulating layer,
wherein the glass fibers include first glass fibers extending in a first horizontal direction and second glass fibers disposed on the first glass fibers and extending in a second horizontal direction,
wherein a cross-section of the first glass fibers and a cross-section of the second glass fibers are disposed on a cross-section of the circuit portion,
wherein the first glass fiber includes a plurality of regions disposed such that its thickness in a vertical direction varies along a third horizontal direction forming a predetermined angle with the first horizontal direction, and the second glass fiber includes a plurality of cross-section portions disposed spaced apart along the third horizontal direction.

2. The circuit board of claim 1, wherein a longitudinal direction of the circuit portion is inclined at a predetermined angle relative to an imaginary axis parallel to a longitudinal direction of the second glass fiber.

3. The circuit board of claim 2, wherein the longitudinal direction of the circuit portion has an angle of 5 degrees or more but less than 22.5 degrees relative to an imaginary axis parallel to the longitudinal direction of the second glass fiber.

4. The circuit board of claim 3, wherein the longitudinal direction of the circuit portion forms an angle of 10 degrees with respect to an imaginary axis parallel to the longitudinal direction of the second glass fiber.

5. The circuit board of claim 1, wherein the multiple regions of the first glass fiber include a first region and a second region having a smaller vertical width than the first region.

6. The circuit board of claim 5, wherein the first region and the second region are disposed alternately along the third horizontal direction.

7. The circuit board of claim 5, wherein a vertical width of the first glass fiber gradually increases when moving from the first region to the second region, and the vertical width of the first glass fiber gradually decreases when moving from the second region to the first region.

8. The circuit board of claim 5, wherein the first glass fiber has a region separated in the third horizontal direction, based on a cross-section perpendicular to the longitudinal direction of the circuit portion.

9. The circuit board of claim 1, wherein based on a cross-section perpendicular to the longitudinal direction of the circuit portion, the multiple cross-section portions of the second glass fiber each have different gaps from the adjacent cross-section portion along the third horizontal direction.

10. The circuit board of claim 9, wherein the second glass fibers include second-1 glass fibers, second-2 glass fibers, and second-3 glass fibers sequentially disposed along the third horizontal direction, wherein the first-1 glass fiber and the second-2 glass fiber form a first gap in the third horizontal direction, and the second-2 glass fiber and the second-3 glass fiber form a second gap in the third horizontal direction, which is different from the first gap.

11. The circuit board of claim 1, wherein based on the circuit portion, the first glass fiber is disposed vertically above the second glass fiber.

12. The circuit board of claim 1, wherein the first glass fiber and the second glass fiber are provided in a form woven with warp and weft threads.

13. The circuit board of claim 1, wherein based on a cross-section perpendicular to the longitudinal direction of the circuit portion, the first glass fiber includes multiple convex portions, while the second glass fiber has a circular cross-sectional shape.

14. The circuit board of claim 1, wherein the third horizontal direction is perpendicular to the longitudinal direction of the circuit portion.

15. The circuit board of claim 1, wherein the circuit board further comprises a via electrode penetrating the insulating layer, and
wherein the via electrode includes:
a first portion having a width gradually decreasing in a vertical direction; and
a second portion adjacent to the first portion and having a width gradually increasing in the vertical direction.

16. A semiconductor package, comprising:
an insulating layer including resin and glass fibers disposed within the resin;
a semiconductor chip disposed on the insulating layer; and
a circuit portion disposed on the insulating layer,
wherein the glass fibers include first glass fibers extending in a first horizontal direction and second glass fibers disposed on the first glass fibers and extending in a second horizontal direction,
wherein a cross-section of the first glass fibers and a cross-section of the second glass fibers are disposed on a cross-section of the circuit portion, wherein the first glass fiber includes a plurality of regions disposed such that its thickness in a vertical direction varies along a third horizontal direction forming a predetermined angle with the first horizontal direction, and the second glass fiber includes a plurality of cross-section portions disposed spaced apart along the third horizontal direction.

17. The semiconductor package of claim 16, wherein a longitudinal direction of the circuit portion is inclined at a predetermined angle relative to an imaginary axis parallel to a longitudinal direction of the second glass fiber.

18. The semiconductor package of claim 17, wherein the longitudinal direction of the circuit portion has an angle of 5 degrees or more but less than 22.5 degrees relative to an imaginary axis parallel to the longitudinal direction of the second glass fiber.

19. The semiconductor package of claim 18, wherein the longitudinal direction of the circuit portion forms an angle of 10 degrees with respect to an imaginary axis parallel to the longitudinal direction of the second glass fiber.

20. The semiconductor package of claim 16, wherein the multiple regions of the first glass fiber include a first region and a second region having a smaller vertical width than the first region.
